(19) United States
(12) Patent Application Publication
(10) Pub. No.: US 2010/0238964 A1
(43) Pub. Date: Sep. 23, 2010

(54) Semiconductor laser structure

(75) Inventors: Noriyuki Matsushita, Nagoya-city (JP); Hitoshi Yamada, Obu-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/659,311

(22) Filed: Mar. 4, 2010

(30) Foreign Application Priority Data
Mar. 19, 2009 (JP) 2009-68510

(51) Int. Cl. H01S 5/34; H01S 5/026; H01S 5/323

(52) U.S. Cl. 372/45.012

(57) ABSTRACT

A semiconductor laser structure includes: a plurality of laser structure units, wherein each laser structure unit includes a N conductive type clad layer, a light emission layer and a P conductive type clad layer, which are stacked in this order; and a tunnel junction layer disposed between two adjacent laser structure units. The tunnel junction layer includes a P conductive type layer and a N conductive type layer. The P conductive type layer includes a dopant of zinc. The N conductive type layer includes a dopant of a group six element.

### CROSS REFERENCE TO RELATED APPLICATION

This application is based on Japanese Patent Application No. 2009-68510 filed on Mar. 19, 2009, the disclosure of which is incorporated herein by reference.

### FIELD OF THE INVENTION

The present invention relates to a semiconductor laser structure.

### BACKGROUND OF THE INVENTION

When a semiconductor laser device is used for an apparatus such as a laser radar apparatus for generating a high power according to a large pulse current, as shown in FIG. 7, multiple laser structure units 101, 103 are stacked on a growing surface of a substrate 105 in a vertical direction of the substrate 105. A first laser structure unit 101 includes a N conductive type clad layer 107, a light emission layer 109 and a P conductive type clad layer 111, which are stacked in this order. A second laser structure unit 103 includes a N conductive type clad layer 113, a light emission layer 115 and a P conductive type clad layer 117, which are stacked in this order.

The P conductive type clad layer 111 in the first laser structure unit 101 is adjacent to the N conductive type clad layer 113 in the second laser structure unit 103. Thus, when the laser device is operated, a reverse bias is applied to an interface between the first and second laser structure units 101, 103, so that the device provides high resistance.

In view of the above point, as shown in FIG. 8, a tunnel junction layer 119 is formed at the interface between the first and second laser structure units 101, 103 so that a resistance in the device is reduced. The tunnel junction layer 119 is composed of a P conductive type layer 121 and a N conductive type layer 123. Each layer 121, 123 has a thickness of a few tens nano meters.

To reduce the resistance effectively, impurities are doped with high impurity concentration in the P conductive type layer 121 and the N conductive type layer 123, respectively. Further, it is required to restrict diffusion of dopants in the P conductive type layer 121 and the N conductive type layer 123.

A dopant used for a semiconductor laser device with a substrate made of GaAs or InP has a large diffusion rate, in general. Thus, it is difficult to restrict the diffusion of dopants. When the diffusion of dopants is not restricted, the resistance of the device increases. As a result, a driving voltage may increase, luminescence efficiency is reduced because of heat generated in the device, and/or reliability is reduced. Thus, when the semiconductor laser device is formed from GaAs material, a P conductive type dopant in the tunnel junction layer 119 is carbon having a comparatively small diffusion rate. This technique has been cited by many documents.

In the above technique, when the p conductive type dopant in the tunnel junction layer is carbon, crystallinity of a layer providing the laser structure is reduced. When the semiconductor laser structure is formed by a MOCVD method (i.e., metal organic chemical vapor deposition method), material of carbon is provided by halogenated carbon such as CCl₄ and CBr₄. The halogenated carbon generates hydrogen halide having etching function after the halogenated carbon is decomposed. Thus, crystallinity of the laser structure is reduced. Further, when the device is formed with using the substrate made of InP, it is impossible to dope the carbon in the tunnel junction layer with high impurity concentration.

Alternatively, a method for restricting diffusion of dopants is disclosed in JP-A-2008-47627 such that semiconductor laser structures are formed on substrates having different conductive types, and then, the substrates are bonded to each other.

In the above feature, a manufacturing method of the semiconductor laser structure is complicated.

### SUMMARY OF THE INVENTION

In view of the above-described problem, it is an object of the present disclosure to provide a semiconductor laser structure with a low resistance and high crystallinity.

According to an aspect of the present disclosure, a semiconductor laser structure includes: a plurality of laser structure units, wherein each laser structure unit includes a N conductive type clad layer, a light emission layer and a P conductive type clad layer, which are stacked in this order; and a tunnel junction layer disposed between two adjacent laser structure units. The tunnel junction layer includes a P conductive type layer and a N conductive type layer. The P conductive type layer includes a dopant of zinc. The N conductive type layer includes a dopant of a group six element.

Since the dopants in the P conductive type layer and the N conductive type layer are restricted from being diffused into other layers, high concentration of the dopants in the P conductive type layer and the N conductive type layer is maintained. As a result, resistance in the semiconductor laser structure with using the tunnel junction layer is reduced. Further, since the P conductive type dopant does not provide etching function after decomposition, crystallinity is not reduced. Further, a manufacturing method of the laser structure is simple.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a semiconductor laser structure;

FIG. 2 is a cross sectional view showing a semiconductor laser structure according to a first example embodiment;

FIG. 3 is a graph showing a concentration profile of Zn in the P conductive type layer and the N conductive type layer;

FIG. 4 is a graph showing a relationship between resistance and carrier concentration in the P conductive type layer and the N conductive type layer;

FIG. 5 is a graph showing a relationship between Se dope concentration in the N conductive type layer and a surface roughness;

FIG. 6 is a cross sectional view showing a semiconductor laser structure according to a second example embodiment;

FIG. 7 is a cross sectional view showing a semiconductor laser structure without a tunnel junction layer;

FIG. 8 is a cross sectional view showing a semiconductor laser structure with a tunnel junction layer;

FIG. 9 is a diagram showing material, thickness, carrier concentration and a dopant of each layer in the semiconductor laser structure according to the first example embodiment; and

FIG. 10 is a diagram showing material, thickness, carrier concentration and a dopant of each layer in the semiconductor laser structure according to the second example embodiment.

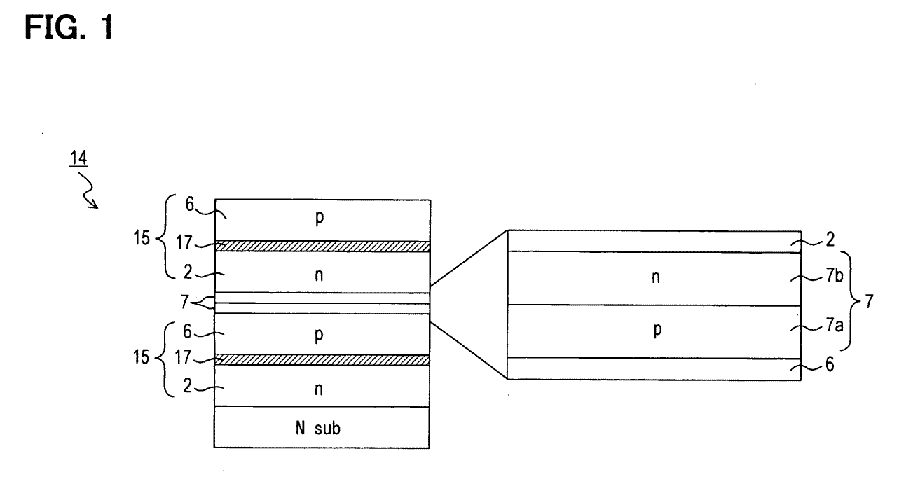

### DETAILED DESCRIPTION OF THE PREFERRED EMBODIMENTS

A semiconductor laser structure 14 according to an example of the present disclosure includes multiple laser structure units 15. Each unit 15 includes a N conductive type clad layer 2, a light emission layer 17 and a P conductive type clad layer 6, which are stacked in this order. A tunnel junction layer 7 is arranged between adjacent two laser structure units 15. The tunnel junction layer 7 includes a P conductive type layer 7a having a Zn dopant and a N conductive type layer 7b having a dopant of a group six element such as Se.

Thus, since the dopant of the P conductive type layer 7a is Zn, and the dopant of the N conductive type layer 7b is a group six element, the dopants in the P conductive type layer 7a and the N conductive type layer 7b are restricted from being diffused to other layers. Specifically, conventionally, it is considered that Zn is easily diffused although Zn has a high doping efficiency and a high activation rate. However, when the laser structure 14 has the above construction, Zn is restricted from being diffused into the N conductive type layer 7b.

Since the dopants in the P conductive type layer 7a and the N conductive type layer 7b are restricted from being diffused into other layers, high concentration of the dopants in the P conductive type layer 7a and the N conductive type layer 7b is maintained. As a result, resistance in the semiconductor laser structure 14 with using the tunnel junction layer 7 is reduced.

Since the resistance of the laser structure 14 is reduced with using the tunnel junction layer 7, increase of a driving voltage, and reduction of luminescence efficiency and reliability caused by heat generated in the structure 14 are restricted.

Since the P conductive type dopant is not carbon, crystallinity is not reduced. Here, carbon is a dopant for providing etching function after decomposition.

Each layer in the laser structure 14 may be formed only by a metal organic chemical vapor deposition method. Thus, a dopant concentration in the tunnel junction layer 7 can be increased without any means for restricting diffusion. Here, any means for restricting diffusion is, for example, another crystal growing method or an ion implantation method. Further, a manufacturing method of the laser structure 14 is simple, compared with a complicated manufacturing method described in JP-A-2008-47627.

The group six element is, for example, S, Se, Te and the like. Specifically, it is easy to handle Se, and further, Se has high doping efficiency and high activation rate. Thus, it is preferable to use Se.

It is preferred that the product of the carrier concentration of the P conductive type layer 7a and the carrier concentration of the N conductive type layer 7b is equal to or higher than 1×10³⁶ cm⁻⁶. In this case, the resistance at the tunnel junction layer 7 is much reduced. Here, the carrier concentration is evaluated by a Hall measurement method or a CV measurement method.

The dopant concentration in the N conductive type layer 7b is preferably in a range between 2×10¹⁷ cm⁻³ and 1×10¹⁹ cm⁻³. When the dopant concentration in the N conductive type layer 7b is equal to or higher than 2×10¹⁷ cm⁻³, the dopant, i.e., Zn in the P conductive type layer 7a is effectively restricted from being diffused into the N conductive type layer 7b. When the dopant concentration in the N conductive type layer 7b is equal to or lower than 1×10¹⁹ cm⁻³, crystallinity of the N conductive type layer 7b and other layers disposed over the N conductive type layer 7b is improved. Here, the dopant concentration is measured by a SIMS (secondary ion mass spectrometer).

The tunnel junction layer 7 may include indium. It is difficult to use carbon as a P conductive type dopant in crystal including indium. Thus, it is necessary to use Zn as a P conductive type dopant in crystal including indium. Here, conventionally, it is considered that Zn in crystal including indium may be easily diffused. However, when the laser structure 14 has the above construction, Zn is restricted from being diffused.

The laser structure may include a substrate made of InP. In this case, in view of a lattice constant, it is preferred that the tunnel junction layer 7 include crystal of In such as InGaAs, InGaAsP, and AlGaInAs.

The thickness of each of the N conductive type layer 7b and the P conductive type layer 7a is preferably equal to or larger than 20 nano meters. The present inventors have discovered that the diffusion length of each of Zn and the group six element, is equal to or smaller than 20 nano meters according to a result of the SIMS. Specifically, when the product of the carrier concentration in the P conductive type layer 7a and the carrier concentration in the N conductive type layer 7b is equal to or larger than 1×10³⁶ cm⁻⁶, the diffusion length of each of Zn and the group six element is equal to or smaller than 20 nano meters. Thus, when the thickness of each of the N conductive type layer 7b and the P conductive type layer 7a is preferably equal to or larger than 20 nano meters, the diffusion of the group six element from the N conductive type layer 7b to the P conductive type layer 7a and the diffusion of Zn from the P conductive type layer 7a to the N conductive type layer 7b are sufficiently restricted. Thus, the reduction of the resistance with using the tunnel junction layer 7 is effectively performed.

Here, the number of the laser structure units 15 is equal to or larger than two.

### First Example Embodiment

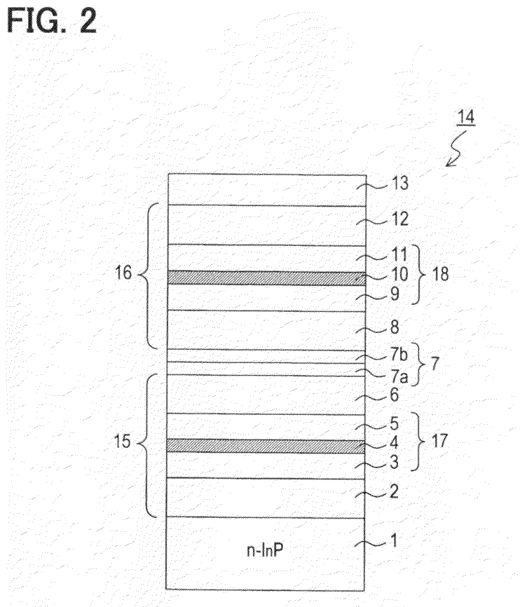

FIG. 2 shows a laser structure 14 according to a first example embodiment. The structure 14 includes a substrate 1 made of N conductive type InP, a N conductive type clad layer 2, a N conductive type waveguide layer 3, a multiple quantum well active layer 4, a P conductive type waveguide layer 5, a P conductive type clad layer 6, a P conductive type layer 7a, a N conductive type layer 7b, a N conductive type clad layer 8, a N conductive type waveguide layer 9, a multiple quantum well active layer 10, a P conductive type waveguide layer 11, a P conductive type clad layer 12, and a P conductive, type contact layer 13, which are stacked in this order. Each layer is formed by a conventional MOCVD method. A substrate temperature in a growth process is in a range between 550° C. and 800° C.

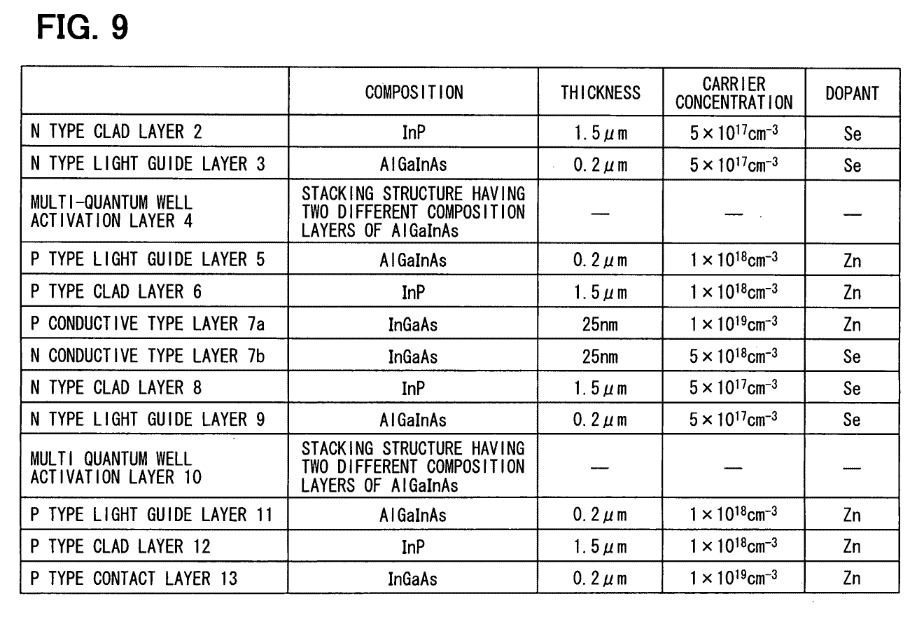

A composition, a thickness, a carrier concentration and a dopant in each layer are shown in FIG. 9.

The N conductive type clad layer 2, the N conductive type waveguide layer 3, the multiple quantum well active layer 4, the P conductive type waveguide layer 5, and the P conductive type clad layer 6 provide a laser structure unit 15. The N conductive type clad layer 8, the N conductive type waveguide layer 9, the multiple quantum well active layer 10, the P conductive type waveguide layer 11, and the P conductive type clad layer 12 provide another laser structure unit 16. The P conductive type layer 7a and the N conductive type layer 7b provide a tunnel junction layer 7. The N conductive type waveguide layer 3, the multiple quantum well active layer 4 and the P conductive type waveguide layer 5 provide a light emission layer 17. The N conductive type waveguide layer 9, the multiple quantum well active layer 10 and the P conductive type waveguide layer 11 provide another light emission layer 18. Thus, the semiconductor laser structure 14 is a stack type semiconductor laser structure having two laser structure units 15, 16, which are stacked in a direction perpendicular to the substrate 1.

The structure 14 may provide a semiconductor laser device. First, an oxide film made of SiO₂ is formed and patterned on the contact layer 13. Then, an electrode made of Cr/Pt/Au is formed on the oxide film. Further, a backside of the substrate 1 is polished so that the thickness of the substrate 1 is equal to 120 micrometers. Another electrode made of Au—Ge/Ni/Au is formed on a polished surface of the substrate 1. Further, thermal treatment is performed at 360° C. for one minute so that electrical contact between each electrode and the semiconductor laser structure 14 is stabilized.

Next, the substrate 1 is cut into rectangles having a width of 500 micrometers by a cleaving method so as to form a resonator. A low reflectivity layer having a low reflectivity with respect to an emitted laser wavelength is formed on one side of the rectangle, and a high reflectivity layer having a high reflectivity with respect to an emitted laser wavelength is formed on the other side of the rectangle. The low and high reflectivity layers are made of, for example, Al₂O₃ and a-Si. Then, the dimensions of the rectangle are adjusted to be predetermined dimensions for a chip. Thus, the semiconductor laser device is completed.

In the above embodiment, a growth layer formed of a InP layer, a AlGaInAs layer, and a InGaAs layer is formed on the substrate 1 made of a N conductive type InP. Alternatively, the substrate may be made of N conductive type GaAs. Alternatively, a growth layer formed of a GaAs layer, a AlGaAs layer, a InGaP layer, a InGaAsP layer and a AlGaInP layer may be formed on a InP or GaAs substrate. The structure 14 includes two units 15, 16. Alternatively, the structure 14 may include three or more units. In this case, one or more tunnel junction layers 7 and one or more laser structure units having the same construction as the unit 16 are arranged between the unit 16 and the contact layer 13.

Materials for providing each element of crystal in each layer are, for example, trimethyl-gallium or triethyl-gallium for providing Ga, trimethyl-aluminum or triethyl-aluminum for Al, trimethyl-indium or triethyl-indium for In, and dimethyl-zinc or diethyl-zinc for Zn. Materials for providing As are, for example, AsH₃ (arsine). Materials for providing P are, for example, PH₃ (phosphine). Materials for providing Se are, for example, H₂Se (hydrogen selenide).

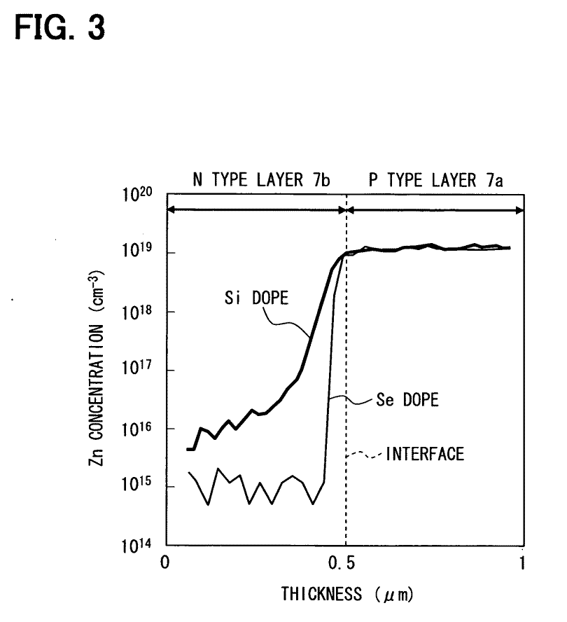

A concentration profile of Zn in the P conductive type layer 7a and the N conductive type layer 7b in a depth direction is measured by a SIMS method. Here, Zn is a dopant in the P conductive type layer 7a. Further, regarding another structure as a comparison has the same structure as the laser structure 14 other than the N conductive type layer 7b with a dopant of Si, a concentration profile of Zn in the P conductive type layer 7a and the N conductive type layer 7b in a depth direction is measured by a SIMS method. The doping concentration of Si in the other structure is 5×10¹⁷ cm⁻³. Here, the structure 14 has the N conductive type layer 7b with a dopant of Se. The result is shown in FIG. 3.

As shown in FIG. 3, when the dopant in the N conductive type layer 7b is Se, i.e., in case of the structure 14, diffusion of Zn into the N conductive type layer 7b is restricted significantly. However, when the dopant in the N conductive type layer 7b is Si, i.e., in case of the other structure, Zn is diffused into the N conductive type layer 7b significantly. Thus, the laser structure 14 restricts the dopant in the P conductive type layer 7a from being diffused into other layers. Thus, resistance of the structure 14 is much reduced.

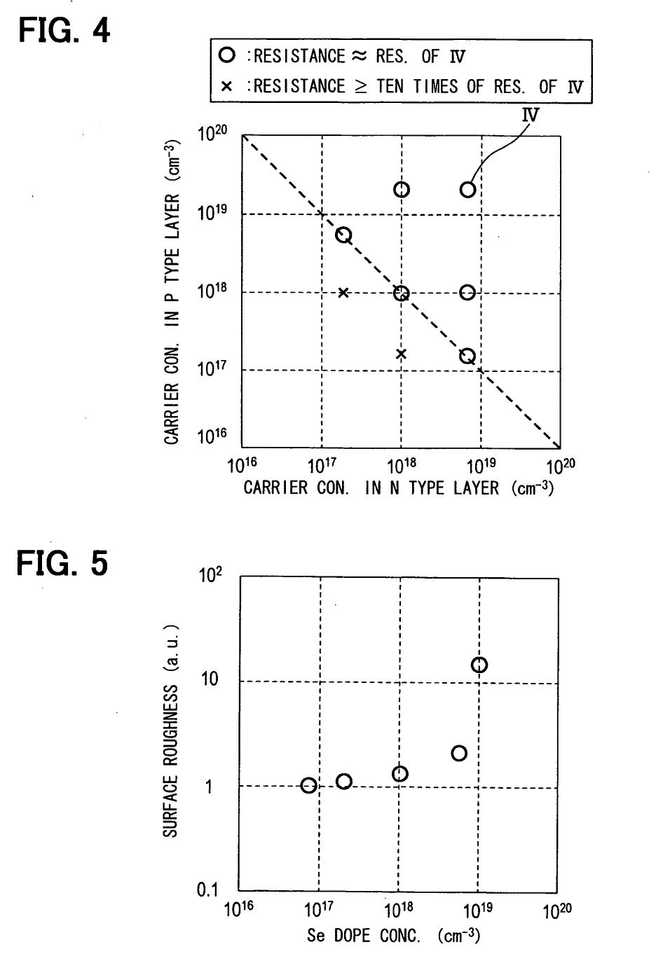

Various semiconductor laser structures having almost the same structure as the structure 14 are manufactured such that the carrier concentration in the N conductive type layer 7a and the carrier concentration in the P conductive type layer 7b are changed. FIG. 4 shows a result. In FIG. 4, a combination of the carrier concentration in the N conductive type layer 7a and the carrier concentration in the P conductive type layer 7b is shown as a circle O or a cross X. The resistance of each laser structure is measured. When the resistance of the structure is almost the same as the resistance of the structure shown as IV, the circle is attached. When the resistance of the structure is ten times equal to or larger than the resistance of the structure shown as IV, the cross X is attached. Here, when the resistance of the structure is ten times equal to or larger than the resistance of the structure shown as IV, the resistance of the structure is almost the same as the structure without the tunnel junction layer 7. As shown in FIG. 4, when the product of the carrier concentration of the P conductive type layer 7a and the carrier concentration of the N conductive type layer 7b is equal to or larger than 1×10³⁶ cm⁻⁶, the resistance of the structure is sufficiently small.

Various semiconductor laser structures having almost the same structure as the structure 14 are manufactured such that the Se dope concentration in the n conductive type layer 7b is changed, as shown in FIG. 5. When the N conductive type layer 7b is completely formed, the surface roughness of the N conductive type layer 7b is measured by a AFM (atomic force microscope). FIG. 5 shows a result. When the Se dopant concentration in the N conductive type layer 7b is smaller than 1×10¹⁹ cm⁻³, the surface roughness is sufficiently small. In general, when crystallinity is excellent, the surface roughness is small. Thus, the result in FIG. 5 shows that the crystallinity of the N conductive type layer 7b and layers formed over the N conductive type layer 7b is excellent when the Se dopant concentration in the N conductive type layer 7b is smaller than 1×10¹⁹ cm⁻³.

### Second Example Embodiment

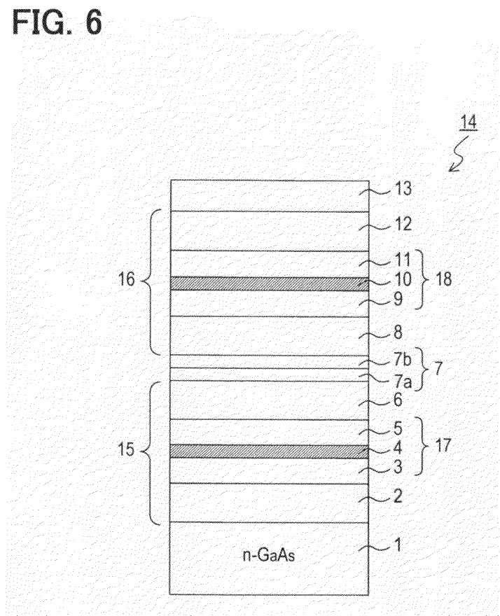

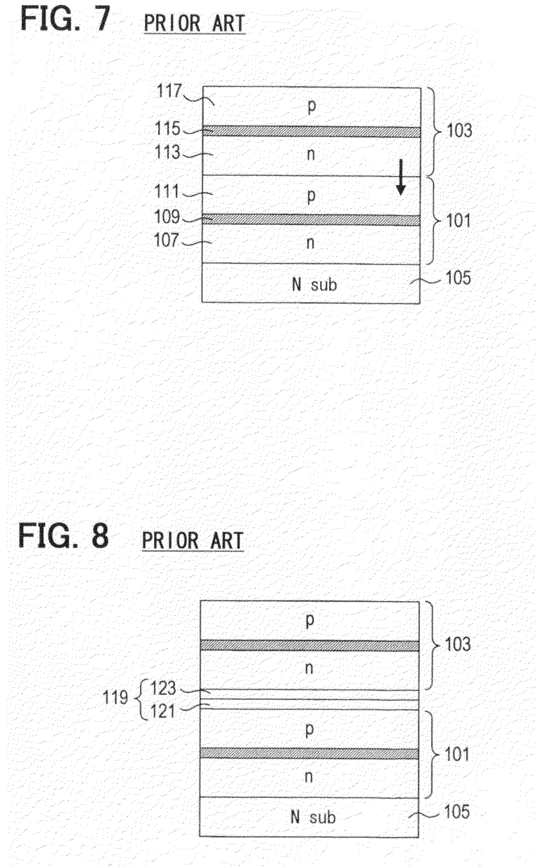

FIG. 6 shows a laser structure 14 according to a second example embodiment. The structure 14 includes a substrate 1 made of N conductive type GaAs, a N conductive type clad layer 2, a N conductive type waveguide layer 3, a multiple quantum well active layer 4, a P conductive type waveguide layer 5, a P conductive type clad layer 6, a P conductive type layer 7a, a N conductive type layer 7b, a N conductive type clad layer 8, a N conductive type waveguide layer 9, a multiple quantum well active layer 10, a P conductive type waveguide layer 11, a P conductive type clad layer 12, and a P conductive type contact layer 13, which are stacked in this order. Each layer is formed by a conventional MOCVD method. A substrate temperature in a growth process is in a range between 550° C. and 800° C.

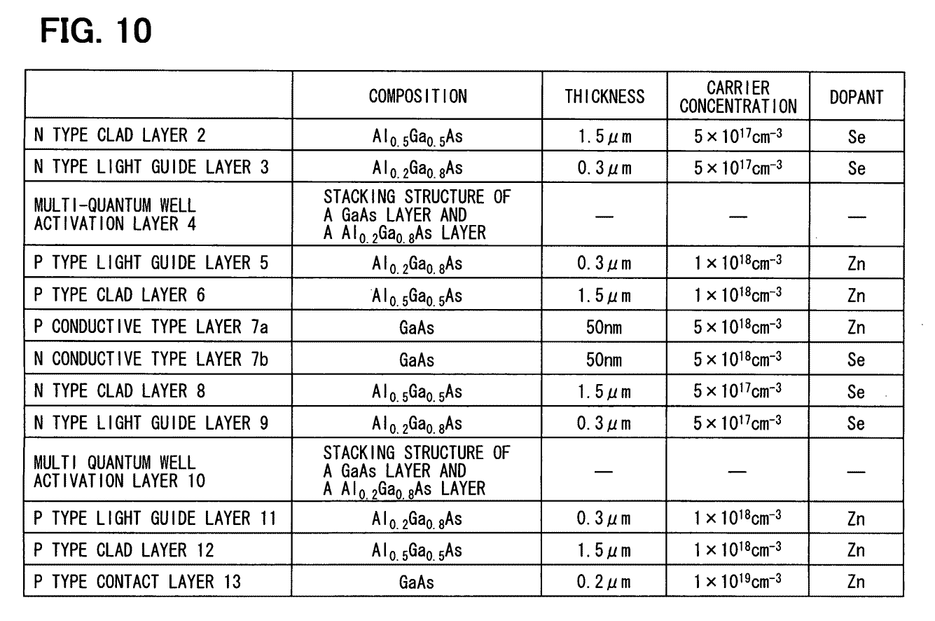

A composition, a thickness, a carrier concentration and a dopant in each layer are shown in FIG. 10.

The N conductive type clad layer 2, the N conductive type waveguide layer 3, the multiple quantum well active layer 4, the P conductive type waveguide layer 5, and the P conductive type clad layer 6 provide a laser structure unit 15. The N conductive type clad layer 8, the N conductive type waveguide layer 9, the multiple quantum well active layer 10, the P conductive type waveguide layer 11, and the P conductive type clad layer 12 provide another laser structure unit 16. The P conductive type layer 7a and the N conductive type layer 7b provide a tunnel junction layer 7. The N conductive type waveguide layer 3, the multiple quantum well active layer 4 and the P conductive type waveguide layer 5 provide a light emission layer 17. The N conductive type waveguide layer 9, the multiple quantum well active layer 10 and the P conductive type waveguide layer 11 provide another light emission layer 18. Thus, the semiconductor laser structure 14 is a stack type semiconductor laser structure having two laser structure units 15, 16, which are stacked in a direction perpendicular to the substrate 1.

The structure 14 may provide a semiconductor laser device. First, an oxide film made of SiO₂ is formed and patterned on the contact layer 13. Then, an electrode made of Cr/Pt/Au is formed on the oxide film. Further, a backside of the substrate 1 is polished so that the thickness of the substrate 1 is equal to 120 micrometers. Another electrode made of Au—Ge/Ni/Au is formed on a polished surface of the substrate 1. Further, thermal treatment is performed at 360° C. for two minutes so that electrical contact between each electrode and the semiconductor laser structure 14 is stabilized.

Next, the substrate 1 is cut into rectangles having a width of 500 micrometers by a cleaving method so as to form a resonator. A low reflectivity layer having a low reflectivity with respect to an emitted laser wavelength is formed on one side of the rectangle, and a high reflectivity layer having a high reflectivity with respect to a laser beam is formed on the other side of the rectangle. The low and high reflectivity layers are made of, for example, Al₂O₃ and a-Si. Then, the dimensions of the rectangle are adjusted to be predetermined dimensions for a chip. Thus, the semiconductor laser device is completed.

In the above embodiment, a growth layer formed of a GaAs layer, and a AlGaAs layer is formed on the substrate 1 made of N conductive type GaAs. Alternatively, the substrate may be made of InP. Alternatively, a growth layer formed of a InP layer, a InGaAs layer, a InGaP layer, a InGaAsP layer, a AlGaInAs layer and a AlGaInP layer may be formed on a InP or GaAs substrate. The structure 14 includes two units 15, 16. Alternatively, the structure 14 may include three or more units. In this case, one or more tunnel junction layers 7 and one or more laser structure units having the same construction as the unit 16 are arranged between the unit 16 and the contact layer 13.

Materials for providing each element of crystal in each layer are, for example, trimethyl-gallium or triethyl-gallium for providing Ga, trimethyl-aluminum or triethyl-aluminum for Al, and dimethyl-zinc or diethyl-zinc for Zn. Materials for providing As are, for example, AsH₃ (arsine). Materials for providing Se are, for example, H₂Se (hydrogen selenide).

The above laser structure 14 in FIG. 6 has almost the same effect as the structure 14 in FIG. 2

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor laser structure comprising:
a plurality of laser structure units, wherein each laser structure unit includes a N conductive type clad layer, a light emission layer and a P conductive type clad layer, which are stacked in this order; and
a tunnel junction layer disposed between two adjacent laser structure units,
wherein the tunnel junction layer includes a P conductive type layer and a N conductive type layer,
wherein the P conductive type layer includes a dopant of zinc, and
wherein the N conductive type layer includes a dopant of a group six element.

2. The semiconductor laser structure according to claim 1,
wherein the group six element is selenium.

3. The semiconductor laser structure according to claim 1,
wherein a product of a carrier concentration of the P conductive type layer and a carrier concentration of the N conductive type layer is equal to or larger than 1×10³⁶ cm⁻⁶.

4. The semiconductor laser structure according to claim 1,
wherein a dopant concentration in the N conductive type layer is equal to or larger than 2×10¹⁷ cm⁻³ and smaller than 1×10¹⁹ cm⁻³.

5. The semiconductor laser structure according to claim 1,
wherein material of the tunnel junction layer includes indium.

6. The semiconductor laser structure according to claim 1, further comprising:
a substrate made of InP.

7. The semiconductor laser structure according to claim 1,
wherein a thickness of the N conductive type layer is equal to or larger than 20 nanometers, and
wherein a thickness of the P conductive type layer is equal to or larger than 20 nanometers.

8. The semiconductor laser structure according to claim 1,
wherein each layer providing the semiconductor laser structure is a metal organic chemical vapor deposition film.

9. The semiconductor laser structure according to claim 1, further comprising:
a substrate made of N conductive type InP,
wherein the light emission layer includes a N conductive type waveguide layer, a multiple quantum well active layer and a P conductive type waveguide layer,
wherein the P conductive type layer contacts the P conductive type clad layer, and
wherein the N conductive type layer contacts the N conductive type clad layer.

10. The semiconductor laser structure according to claim 9,
wherein the N conductive type clad layer includes a dopant of a group six element, and
wherein the N conductive type waveguide layer includes a dopant of a group six element,
wherein the P conductive type waveguide layer includes a dopant of zinc, and
wherein the P conductive type clad layer includes a dopant of zinc.

11. The semiconductor laser structure according to claim 10,
wherein the N conductive type clad layer is made of InP,
wherein the N conductive type waveguide layer is made of AlGaInAs,
wherein the multiple quantum well active layer is made of AlGaInAs, and includes two different composition layers, which are stacked,
wherein the P conductive type waveguide layer is made of AlGaInAs,
wherein the P conductive type clad layer is made of InP,
wherein the P conductive type layer is made of InGaAs, and
wherein the N conductive type layer is made of InGaAs.

12. The semiconductor laser structure according to claim 1, further comprising:
a substrate made of N conductive type GaAs,
wherein the light emission layer includes a N conductive type waveguide layer, a multiple quantum well active layer and a P conductive type waveguide layer,
wherein the P conductive type layer contacts the P conductive type clad layer, and
wherein the N conductive type layer contacts the N conductive type clad layer.

13. The semiconductor laser structure according to claim 12,
wherein the N conductive type clad layer includes a dopant of a group six element, and
wherein the N conductive type waveguide layer includes a dopant of a group six element,
wherein the P conductive type waveguide layer includes a dopant of zinc, and
wherein the P conductive type clad layer includes a dopant of zinc.

14. The semiconductor laser structure according to claim 13,
wherein the N conductive type clad layer is made of AlGaAs,
wherein the N conductive type waveguide layer is made of AlGaAs,
wherein the multiple quantum well active layer includes a first layer made of GaAs and a second layer made of AlGaAs,
wherein the P conductive type waveguide layer is made of AlGaAs,
wherein the P conductive type clad layer is made of AlGaAs,
wherein the P conductive type layer is made of GaAs, and
wherein the N conductive type layer is made of GaAs.
